(19) United States
(12) Patent Application Publication
(10) Pub. No.: US 2008/0042638 A1
(43) Pub. Date: Feb. 21, 2008

(54) Connector with AC/DC Test LEDs

(75) Inventors: Shih-Ming Hwang, Irvine, CA (US); Chien-Jone Hwang, Irvine, CA (US); Liang-Lun Hwang, Irvine, CA (US)

Correspondence Address: PAI PATENT & TRADEMARK LAW FIRM, 1001 FOURTH AVENUE, SUITE 3200, SEATTLE, WA, 98154, US

(73) Assignee: Shih-Ming Hwang, Irvine, CA (US)

(21) Appl. No.: 11/459,021

(22) Filed: Jul. 21, 2006

(51) Int. Cl. G01R 19/14

(52) U.S. Cl. 324/133

(57) ABSTRACT

A connector with AC/DC test LEDs is formed of a pair of different colored LEDs connected in parallel to each other in a test and alarm circuit which is connected to a power source. One LED is forward-biased, while the other reverse-biased. If the power source to which the connector is connected is AC, both LEDs are turned on. If that power source is DC and the circuit is connected with correct polarity, only the forward-biased LED is turned on. If that power source is DC and the polarity is reverse-connected, only the reverse-biased LED is turned on. With this scheme, hazardous accidents and electrical damage can be prevented.

### BACKGROUND OF THE INVENTION

1. Field of the Invention

The present invention relates to a connector with AC/DC test LEDs, and more particularly, to a connector with AC/DC test LEDs which is able to detect and indicate via built-in LEDs the state of electrical components connected to an electrical connector so as to protect any circuits, connectors, and electrical and electronic devices connected via the present invention.

2. Description of the Prior Art

Commonly used electrical and electronic devices and components are often installed at particular locations according to the requirements of specific applications. Many, if not most, of these applications specify that either AC or DC power must be used, and further require a power supply with a specific voltage. If such devices or components are connected to an incorrect power supply, they may not only fail to operate normally, but also might be ruined. So it is very important to develop a special connector which is able to ensure a device or component is connected to the correct type of power supply without the fear of its being ruined. For example, a closed-circuit TV (CCTV) camera is typically installed in a concealed place such as in a ceiling cavity, in a corner, or on a column or beam where there is no available power source. In such a case, it must be connected to a distant power source using an extension cord. It is typically quite difficult to distinguish a DC power source from an AC power source without the aid of a testing instrument, thus leading to possible wrong power connections and damage to the camera. Also, reversing the polarity of a DC power source may also cause such damage. Such damage could result in a fire or in a reduction of the security expected from using such cameras.

For these defects in the prior art, an improvement is urgently required. The applicant has dedicated great efforts for years to study how to eliminate these defects and has finally come up with a novel connector with AC/DC test LEDs as provided in this invention.

### SUMMARY OF THE INVENTION

Accordingly, the main object of the present invention is to provide a connector with AC/DC test LEDs capable of detecting the state of an electrical connection and indicating that result via the LEDs so as to protect the circuit and connected loads.

To achieve the above object, the present invention provides a power connector with a pair of different colored LEDs connected in parallel to the power circuit. If the voltage/current signal in the power circuit is tested to be AC, both LEDs will be turned on to emit two different colored lights. If the voltage/current signal appears to be DC connected with the correct polarity, only one of the two LEDs will be turned on. If, however, the signal is DC and the DC polarity is reversed, the other LED will be turned on. The above mentioned three different lighting states of the LEDs can be used to assure the user whether or not the power circuit is connected appropriately.

### BRIEF DESCRIPTION OF THE DRAWINGS

The drawings disclose illustrative embodiments of the present invention which serve to exemplify the various advantages and objects hereof, and are as follows:

FIG. 1 is a schematic view in a first embodiment of the present invention;

FIG. 2 is a schematic view in a second embodiment of the present invention;

FIG. 3 is a schematic view in a third embodiment of the present invention.

### DETAILED DESCRIPTION OF THE PREFERRED EMBODIMENT

For further understanding of the nature and objects of the invention, reference should be made to the following detailed description taken in conjunction with the aforementioned accompanying drawings.

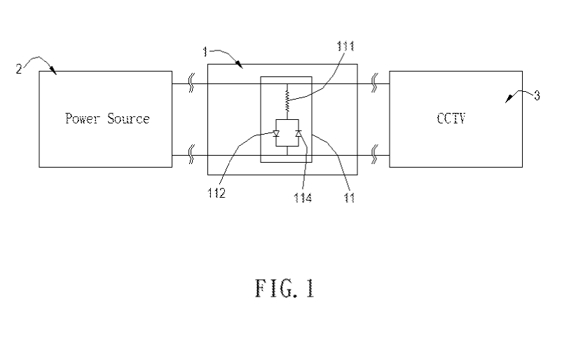

Referring to FIG. 1, in the first embodiment of the present invention, a test and alarm circuit 11 is connected to the circuit including a connector 1. The test and alarm circuit 11 includes a first resistance 111, a forward-biased first LED 112 connected in series with the first resistance 111, and a reverse-biased second LED 114 connected in parallel with first LED 112. The two LEDs 112 and 114 emit lights of different colors.

Circuit 11 is connected to a power source 2 which supplies power to a closed-circuit TV (CCTV) camera 3 or other electronic or electrical devices. As shown in FIG. 1, after camera 3 is installed in its physical location, it is then connected to power source 2 via connector 1 to be energized. The type, AC or DC, of power source 2 and its polarity are discriminated by its voltage/current signal output to test and alarm circuit 11. If both LEDs 112 and 114 are turned on and two different colored lights are observed, this indicates to the user that power source 2 has been identified to be AC. If both LEDs 112 and 114 fail to turn on, either connector 1 or power source 2 is out of order, regardless of whether power source 2 is an AC-type or DC-type of power source, thereby reminding the user to check to see if connector 1 and power source 2 are connected together properly. If only forward-biased LED 112 is turned on, it means that the voltage/current signal inputted into test and alarm circuit 11 from power source 2 is DC, and that power source 2 has the correct polarity. In the case that connector 1 is connected with reverse polarity, only reverse-biased LED 114 is turned on since there is a reverse DC flowing in the circuit, thus reminding the user to reverse the connector terminals or interrupt the power supply from power source 2 at once so as to prevent electrical damage to connector 1 and any equipment such as CCTV 3 or other electrical and electronic devices connected to connector 1.

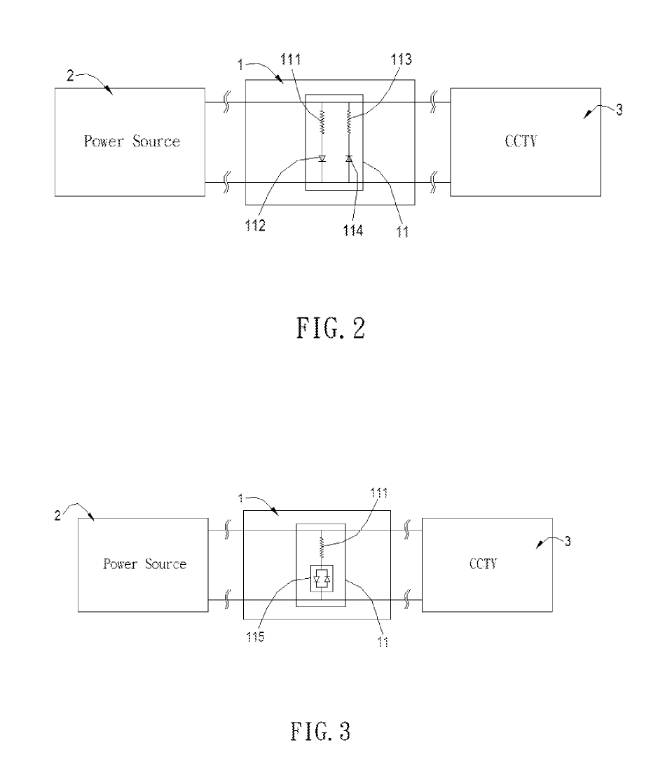

In the second embodiment of the present invention shown in FIG. 2, test and alarm circuit 11 is formed of two branch circuits connected in parallel, one of which includes a first resistance 111 in series with forward-biased LED 112, the other of which includes a second resistance 113 in series with reverse-biased LED 114.

In the third embodiment of the present invention shown in FIG. 3, test and alarm circuit 11 is formed of first resistance 111 in series with a twin-LED 115.

In all, the present invention provides several advantages over the prior art which can be summarized as follows:
1. When power source 2 is of AC-type, whether the circuit between power source 2 and connector 1 is electrically connected or not is judged by test and alarm circuit 11. If connected, both LEDs turn on.
2. When power source 2 is of DC-type, whether the circuit between power source 2 and connector 1 is electrically connected with correct polarity or not is judged by test and alarm circuit 11. If correct, the forward-biased LED 112 turns on; if not, the reverse-biased LED 114 turns on so as to remind the user to interrupt the supply of power from power source 2 at once so as to prevent electrical damage to connector 1 and any equipment such as CCTV 3 or other electrical and electronic devices connected to connector 1.
3. With this scheme, possible disasters such as fires, explosions, and electrocution can be more easily avoided than when using the prior art.

Many changes and modifications in the above-described embodiments of the invention can, of course, be carried out without departing from the scope thereof. Accordingly, to promote the progress in science and the useful arts, the invention is disclosed and is intended to be limited only by the scope of the appended claims.

What is claimed is:

1. A connector with AC/DC test LEDs comprising a test and alarm circuit, said test and alarm circuit comprising a forward-biased LED and a reverse-biased LED connected in parallel, wherein said test and alarm circuit discriminates whether a power source to which said connector is connected is AC or DC, and judges the polarity of said connector with respect to said power source according to a voltage/current signal output from said power source, and indicates the results with light output from said LEDs.

2. The connector of claim 1, wherein said test and alarm circuit further includes a first resistance connected in series with said parallelly-connected LEDs.

3. The connector of claim 1, wherein said test and alarm circuit includes two branch circuits connected in parallel to each other, one of which is formed of a first resistance in series with the forward-biased LED, and the other of which is formed of a second resistance in series with the reverse-biased LED.

4. The connector of claim 2, wherein the forward-biased LED and the reverse-biased LED form a twin-LED.

5. The connector of claim 1, wherein said two LEDs emit light with different colors.
